(19) United States
(12) Patent Application Publication
(10) Pub. No.: US 2026/0293485 A1
(43) Pub. Date: Sep. 24, 2026

(54) DISPLAY MODULE AND ELECTRONIC DEVICE INCLUDING THE DISPLAY MODULE

(71) Applicant: SAMSUNG DISPLAY CO., LTD., YONGIN-SI (KR)

(72) Inventors: TAEMIN KIM, Yongin-si (KR); SUJI PARK, Yongin-si (KR); SEUNGHEE LEE, Yongin-si (KR)

(21) Appl. No.: 19/459,221

(22) Filed: Jan. 26, 2026

(30) Foreign Application Priority Data
Mar. 18, 2025 (KR) 10-2025-0034503

(51) Int. Cl. H10K 59/38; H10K 59/40; H10K 59/80; H10K 102/00

(52) U.S. Cl. CPC H10K 59/38; H10K 59/40; H10K 59/8731; H10K 59/8791; H10K 2102/351

(57) ABSTRACT

A display module includes a base layer. A display element layer is disposed on the base layer and includes light emitting elements. An input sensing layer is disposed on the display element layer. A color filter layer is disposed on the input sensing layer. The color filter layer includes a filter partition wall having filter opening portions defined therein and a plurality of color filters respectively disposed in the filter opening portions. An overcoat layer covers the filter partition wall and the plurality of color filters. The overcoat layer has a Young's modulus in a range of about 3 GPa to about 7 GPa and a degree of planarization in a range of about 90% to about 100%.

### CROSS-REFERENCE TO RELATED APPLICATIONS

This application claims priority under 35 U.S.C. § 119 to Korean Patent Application No. 10-2025-0034503, filed on Mar. 18, 2025 in the Korean Intellectual property Office, the disclosure of which is incorporated by reference in its entirety herein.

### 1. TECHNICAL FIELD

The present disclosure herein relates to a display module, and more particularly, to a display module with increased impact resistance.

### 2. DISCUSSION OF RELATED ART

Display modules are being applied to an increasing number of multimedia apparatuses, such as televisions, mobile phones, tablet computers and game consoles. Research is being conducted concerning a display module having a small thickness to produce display panels having various shapes and for increased user convenience. However, the display module having the small thickness may exhibit decreased impact resistance and be susceptible to damage from external impacts and the like.

### SUMMARY

The present disclosure provides a display module which secures sufficient reliability without including a polarizing layer and a cover glass.

According to an embodiment of the present inventive concept, a display module includes a base layer. A display element layer is disposed on the base layer and includes light emitting elements. An input sensing layer is disposed on the display element layer. A color filter layer is disposed on the input sensing layer. The color filter layer includes a filter partition wall having filter opening portions defined therein and a plurality of color filters respectively disposed in the filter opening portions. An overcoat layer covers the filter partition wall and the plurality of color filters. The overcoat layer has a Young's modulus in a range of about 3 GPa to about 7 GPa and a degree of planarization in a range of about 90% to about 100%.

In an embodiment, the overcoat layer may have a thickness in a range of about 5 μm to about 20 μm.

In an embodiment, the overcoat layer may have a thickness in a range of about 5 μm to about 15 μm.

In an embodiment, the overcoat layer may include at least one material selected from polyhedral oligomeric silsesquioxane (POSS), cyclic epoxy-based resin, and acrylic resin.

In an embodiment, the overcoat layer may have a refractive index in a range of about 1.5 to about 1.6.

In an embodiment, the overcoat layer may have a visible light transmittance greater than or equal to about 99%.

In an embodiment, the overcoat layer may be in direct contact with the filter partition wall and the plurality of color filters.

In an embodiment, the overcoat layer may have a single-layer structure.

In an embodiment, the display module may further include an anti-reflective layer disposed on the overcoat layer.

In an embodiment, the display module may have a total thickness in a range of about 0.1 mm to about 0.55 mm.

In an embodiment, the plurality of color filters comprises first to third color filters. The first color filter may transmit red light. The second color filter may transmit green light. The third color filter may transmit blue light.

In an embodiment, the base layer may comprise glass and may have a thickness less than or equal to about 0.2 mm.

In an embodiment, the input sensing layer may include a sensing insulating layer, a sensing metal layer disposed on the sensing insulating layer, and a passivation layer covering the sensing metal layer.

In an embodiment, the display element layer may include a first inorganic encapsulation layer covering the light emitting elements, an organic encapsulation layer disposed on the first inorganic encapsulation layer, and a second inorganic encapsulation layer disposed on the organic encapsulation layer.

According to an embodiment of the present inventive concept, a display module includes a base layer. A display element layer is disposed on the base layer and includes light emitting elements. An input sensing layer is disposed on the display element layer. A color filter layer is disposed on the input sensing layer and includes a filter partition wall having filter opening portions defined therein and a plurality of color filters respectively disposed in the filter opening portions. An overcoat layer is in direct contact with the filter partition wall and the plurality of color filters. The overcoat layer has a Young's modulus in a range of about 3 GPa to about 7 GPa, and includes at least one material selected from polyhedral oligomeric silsesquioxane (POSS), cyclic epoxy-based resin, and acrylic resin.

In an embodiment, the overcoat layer may have a refractive index in a range of about 1.5 to about 1.6.

In an embodiment, the overcoat layer may have a visible light transmittance greater than or equal to about 99%.

In an embodiment, the overcoat layer may have a thickness in a range of about 5 μm to about 15 μm.

In an embodiment, the display module may further include an anti-reflective layer disposed on the overcoat layer.

According to an embodiment of the present inventive concept, an electronic device includes a display module including a base layer, a display element layer disposed on the base layer and including light emitting elements, an input sensing layer disposed on the display element layer, a color filter layer disposed on the input sensing layer and including a filter partition wall having filter opening portions defined therein, and a plurality of color filters respectively disposed in the filter opening portions, and an overcoat layer covering the filter partition wall and the first to third color filters and having a Young's modulus in a range of about 3 GPa to about 7 GPa and a degree of planarization in a range of about 90% to about 100%. An anti-reflective layer is disposed on the display module. A window is disposed on the anti-reflective layer, a processor electrically connected to the display module. A housing provides a base space in which the display module is disposed.

### BRIEF DESCRIPTION OF THE DRAWINGS

The accompanying drawings are included to provide a further understanding of embodiments of the present inventive concept, and are incorporated in and constitute a part of this specification. The drawings illustrate embodiments of the present inventive concept and, together with the description, serve to explain principles of the present inventive concept. While each drawing may represent one or more particular embodiments of the present disclosure, the present invention is not necessarily limited to the relative lengths, thicknesses and angles shown. In the drawings:

FIG. 1 is a block diagram of an electronic device according to an embodiment of the present inventive concept;

FIG. 2 is a schematic view of electronic devices according to various embodiments of the present inventive concept;

FIG. 3 is a perspective view of an electronic device according to an embodiment of the present inventive concept;

FIG. 4 is an exploded perspective view of an electronic device according to an embodiment of the present inventive concept;

FIG. 5 is an exploded perspective view of a display module according to an embodiment of the present inventive concept;

FIG. 6 is a cross-sectional view of a display module taken along line I-I′ in FIG. 5 according to an embodiment of the present inventive concept;

FIG. 7 is an enlarged view of area AA′ in FIG. 6 according to an embodiment of the present inventive concept; and

FIG. 8 is a graph illustrating experimental results for an embodiment of the present inventive concept and a comparative example.

### DETAILED DESCRIPTION OF EMBODIMENTS

The present inventive concept may be modified in various forms, and particular non-limiting embodiments thereof will be illustrated in the drawings and described herein in detail.

The present inventive concept should not be construed as necessarily limited to the described embodiments set forth herein.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween. When an element is referred to as being “directly on”, “directly connected to” or “directly coupled to” another element, no intervening elements may be present.

Like reference symbols refer to like elements throughout. In the drawings, the thickness, ratio, and size of the elements may be exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the present inventive concept. Similarly, a second element could be termed a first element. In this specification, the singular expressions “a”, “an” and “the” are intended to include the plural forms as well, unless the context clearly indicates otherwise.

In addition, the terms “below”, “on the lower side”, “above”, “on the upper side”, or the like are used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present inventive concept are described with reference to the drawings.

A display module includes an overcoat layer disposed on the color filter layer. The overcoat layer performs both a planarization function and an impact dispersion function. The overcoat layer has a Young's modulus and thickness to provide increased impact resistance. Therefore, the display module may have increased reliability and a relatively small thickness for increased compactness.

The overcoat layer may have a single-layer structure to provide a simple and efficient manufacturing process. The overcoat layer OC may include polyhedral oligomeric silsesquioxane (POSS), cyclic epoxy-based resin, and/or acrylic resin. The overcoat layer may provide sufficient strength to the display module without the inclusion of a cover glass and polarizing layer in the display module.

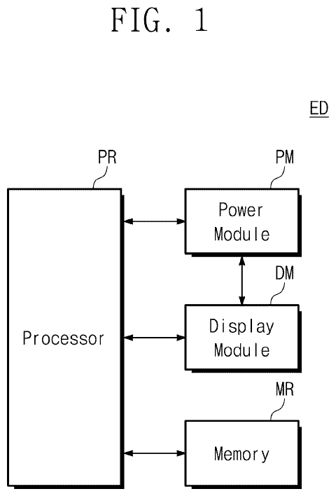

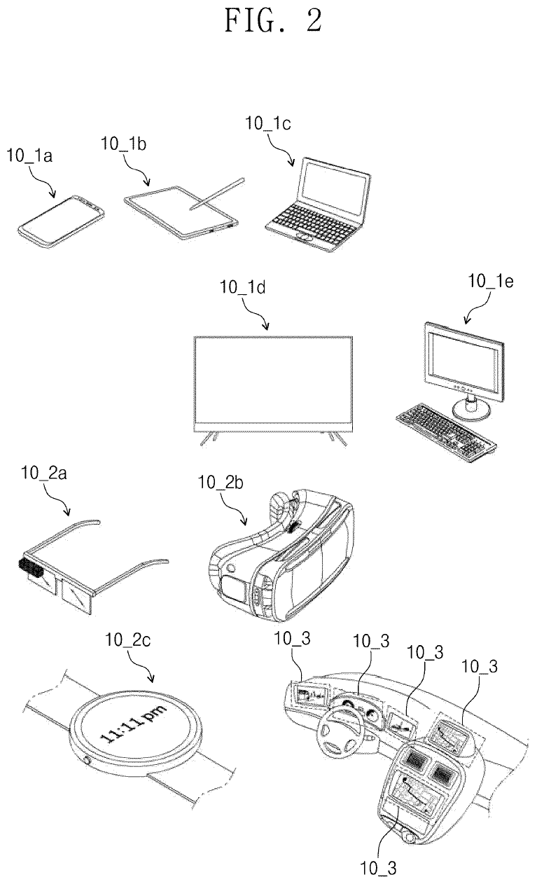

FIG. 1 is a block diagram of an electronic device according to an embodiment of the present inventive concept. FIG. 2 is a schematic view of electronic devices according to various embodiments of the present inventive concept.

FIG. 1 is a block diagram of an electronic device according to an embodiment of the present inventive concept.

The electronic device according to an embodiment of the present inventive concept may be provided in various types. The electronic device according to an embodiment of the present inventive concept may further include a module or device having another additional function.

Referring to FIG. 1, an electronic device ED according to an embodiment may include a display module DM, a processor PR, a memory MR, and a power module PM.

In an embodiment, the processor PR may include at least one of a central processing unit (CPU), an application processor (AP), a graphic processing unit (GPU), a communication processor (CP), an image signal processor (ISP), or a controller.

The memory MR may store data information necessary for an operation of the processor PR or the display module DM. When the processor PR executes an application stored in the memory MR, an image data signal and/or an input control signal may be transmitted to the display module DM, and the display module DM may process the received signal and output image information through a display screen.

In an embodiment, the power module PM may include a power supply module such as a power adapter or a battery device, and a power conversion module which converts the power supplied by the power supply module and generates power necessary for an operation of the electronic device ED.

Some of individual modules included as functional in one module may be included in the display module DM, and others may be provided in the electronic device ED separately from the display module DM.

FIG. 2 is a schematic view of electronic devices according to various embodiments.

Referring to FIG. 2, the electronic devices according to various embodiments may include not only an electronic device for image display, e.g., a smartphone ED_1a, a tablet personal computer ED-1b, a laptop personal computer ED-1c, television ED-1d, and a monitor for a desktop computer ED-1e, but also a wearable electronic device including a display module, e.g., smart glasses ED-2a, a head mounted display ED-2b, and a smart watch ED-2c, and a vehicle electronic device ED-3 including a display module, e.g., a vehicle instrument panel, a center fascia, a center information display (CID) disposed on a dashboard, and a room mirror display. However, embodiments of the present disclosure are not necessarily limited thereto and the electronic devices may be various other small-sized, medium-sized or large-sized electronic devices.

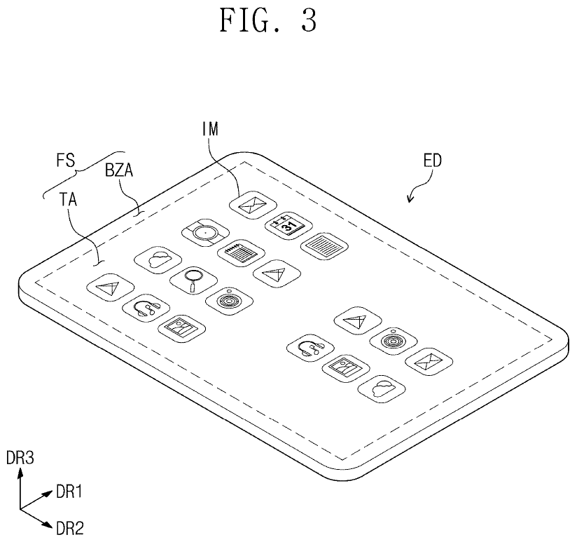

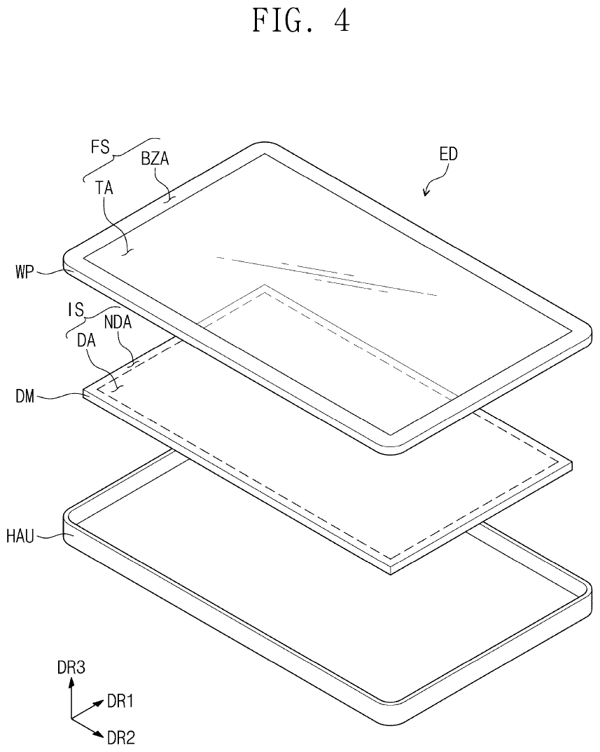

FIG. 3 is a perspective view of an electronic device according to an embodiment of the present inventive concept. FIG. 4 is an exploded perspective view of an electronic device according to an embodiment of the present inventive concept.

In this embodiment, an electronic device ED may have a rectangular shape having relatively short sides extending in a first direction DR1, and having relatively long sides extending in a second direction DR2 on a plane (e.g., in a plan view). However, embodiments of the present inventive concept are not necessarily limited thereto, and the electronic device ED may have various shapes such as a circular shape and a polygonal shape (e.g., in a plan view).

The electronic device ED may display an image IM in a third direction DR3 through a display surface FS parallel to a plane defined by the first direction DR1 and the second direction DR2. The third direction DR3 may be substantially parallel to a normal direction to the display surface FS. The display surface FS on which the image IM is displayed may correspond to a front surface of the electronic device ED. The image IM may include at least one dynamic image and/or still image. FIG. 3 illustrates software application icon images as one example of the image IM.

In this embodiment, a front surface (e.g., top surface) and a rear surface (e.g., a bottom surface) of each of members or units may be defined on the basis of a direction in which the image IM is displayed. The front surface and the rear surface may oppose each other in the third direction DR3, and a normal direction to each of the front surface and the rear surface may be parallel to the third direction DR3. A separation distance between the front surface and the rear surface, which is defined along the third direction DR3, may correspond to a thickness of a member (or unit).

The term “on a plane” or “in a plan view” used herein may be defined as being in a state when viewed in the third direction DR3. The term “on a cross-section” used herein may be defined as being in a state when viewed in the first direction DR1 or the second direction DR2. Directions indicated by the first to third directions DR1, DR2 and DR3 are relative concepts and may be changed to other directions. For example, while in an embodiment shown in FIG. 3 the first to third directions DR1 to DR3 are perpendicular to each other, embodiments of the present inventive concept are not necessarily limited thereto and the first to third directions DR1 to DR3 may intersect each other in various different angles.

In the electronic device ED, the display surface FS on which the image IM is displayed may correspond to a front surface of the electronic device ED and may correspond to a front surface FS of a window WP (see FIG. 4). Hereinafter, the display surface and the front surface of the electronic device ED, and the front surface of the window WP are designated by like reference symbols. In an embodiment, the electronic device ED may include a foldable display device including a folding area and a non-folding area, a bendable display device including at least one bending portion, or the like.

Referring to FIG. 4, the electronic device ED according to this embodiment may include the window WP, a display module DM, and a housing HAU.

The window WP may include an optically transparent insulating material. The window WP may include a transmission area TA and a bezel area BZA. A user may see an image provided through the transmission area TA corresponding to the front surface FS of the window WP.

The transmission area TA may be an optically transparent area. The bezel area BZA may be an area having a relatively low light transmittance compared to the transmission area TA. The bezel area BZA may have a certain color. In an embodiment, the bezel area BZA may be adjacent to the transmission area TA and surround the transmission area TA (e.g., in a plan view). The bezel area BZA may define a shape of the transmission area TA. However, embodiments of the present inventive concept are not necessarily limited to the illustrated embodiment, and the bezel area BZA may be disposed adjacent to only one side of the transmission area TA, or a portion thereof may be omitted.

FIGS. 3 and 4 illustrate the transmission area TA having a rectangular shape (e.g., in a plan view). However, this is illustrated as an example, and the transmission area TA may have various shapes and is not necessarily limited to any one embodiment.

The display module DM may be disposed below the window WP (e.g., in a direction opposite to the third direction DR3). The display module DM may be a component that substantially generates the image IM. The image IM generated by the display module DM is displayed on a display surface IS of the display module DM and is externally visible to a user through the transmission area TA.

The display module DM includes a display area DA and a non-display area NDA. The display area DA may be an area which is activated in response to an electrical signal. The non-display area NDA may be an area which is covered by the bezel area BZA. The non-display area NDA is adjacent to the display area DA. The non-display area NDA may surround the display area DA (e.g., in a plan view).

The housing HAU may accommodate the display module DM. The housing HAU may provide a base space in which the display module DM is disposed. The housing HAU may be arranged to cover the display module DM so that a top surface that is the display surface IS of the electronic device ED is exposed. In an embodiment, the housing HAU may cover a side surface and a bottom surface but expose the entire top surface of the display module DM. However, embodiments of the present inventive concept are not necessarily limited thereto, and the housing HAU may cover not only the side surface and the bottom surface but also a portion of the top surface of the display module DM.

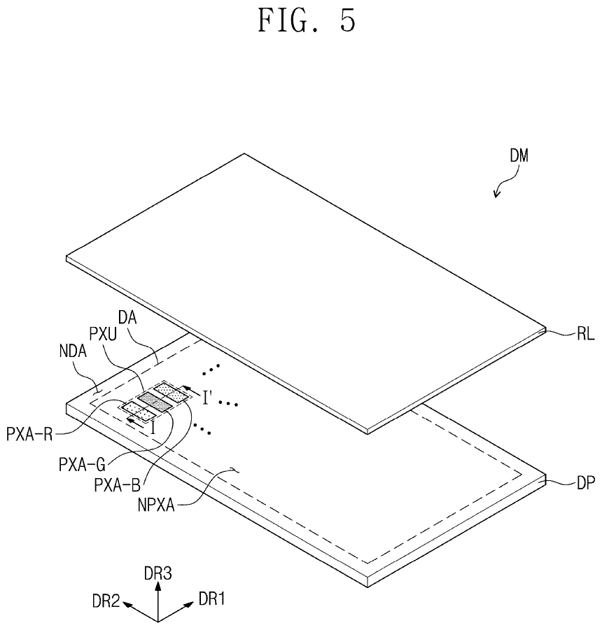

FIG. 5 is an exploded perspective view of a display module according to an embodiment of the present inventive concept.

A display module DM according to an embodiment of the present inventive concept may include a display panel DP and an anti-reflective layer RL disposed on the display panel DP (e.g., in the third direction DR3). The display module DM according to an embodiment of the present inventive concept might not include a cover glass and a polarizing layer.

The display panel DP may include a display area DA and a non-display area NDA adjacent to the display area DA. In an embodiment, the display area DA may include first to third emission areas PXA-R, PXA-G and PXA-B and a non-emission area NPXA.

The first to third emission areas PXA-R, PXA-G and PXA-B may constitute pixel units PXU. The pixel units PXU may be arranged in the first direction DR1 and the second direction DR2. As an example, FIG. 5 illustrates the first emission area PXA-R, the second emission area PXA-G, and the third emission area PXA-B which are arranged within one pixel unit PXU along the first direction DR1. However, the number and the arrangement of the first to third emission areas PXA-R, PXA-G and PXA-B constituting one pixel unit PXU are not necessarily limited to the illustrated embodiment.

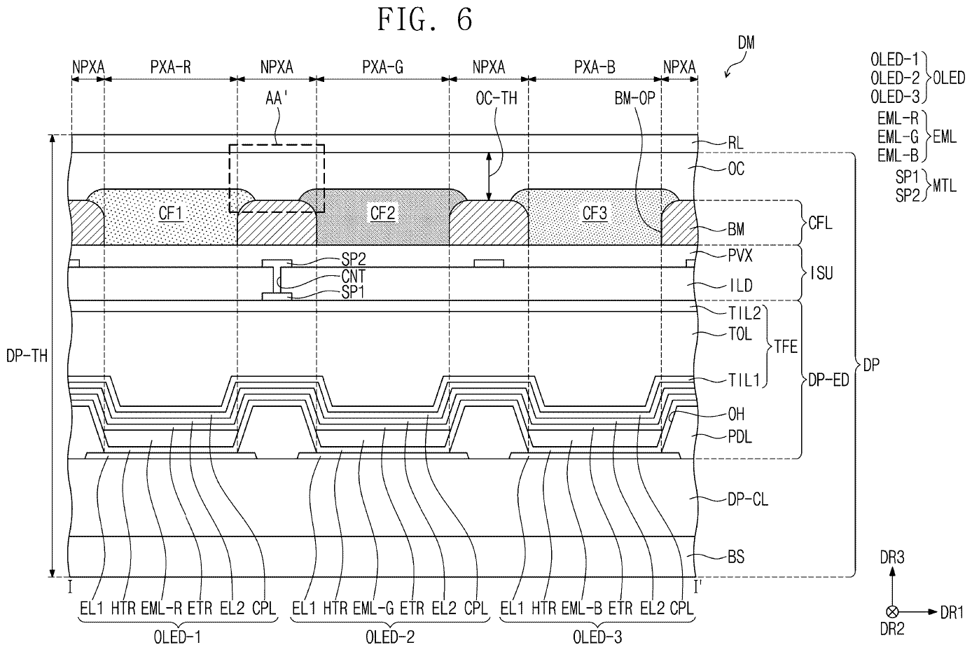

FIG. 6 is a cross-sectional view of a display module taken along line I-I′ in FIG. 5.

A display module DM according to an embodiment of the present inventive concept may include a display panel DP and an anti-reflective layer RL disposed on the display panel DP.

The display panel DP according to an embodiment of the present inventive concept may include a base layer BS, a circuit element layer DP-CL, a display element layer DP-ED, an input sensing layer ISU, a color filter layer CFL, and an overcoat layer OC.

In an embodiment, the base layer BS may have a thickness BS-TH (e.g., length in the third direction DR3) in a range of about 0.2 mm or less. In an embodiment, the base layer BS may include glass.

The circuit element layer DP-CL may be disposed on the base layer BS (e.g., disposed directly thereon in the third direction DR3). The circuit element layer DP-CL may include a plurality of insulating layers. The insulating layers may correspond to an organic layer or an inorganic layer. Conductive patterns may be patterned between the insulating layers. The conductive patterns may constitute a transistor or the like.

The display element layer DP-ED may be disposed on the base layer BS (e.g., in the third direction DR3). In an embodiment, the display element layer DP-ED may include a pixel defining layer PDL in which a pixel opening portion OH is defined, light emitting elements OLED each disposed in the pixel opening portion OH, and an encapsulation layer TFE.

In an embodiment, the light emitting elements OLED may include a first light emitting element OLED1, a second light emitting element OLED2, and a third light emitting element OLED3. However, embodiments of the present inventive concept are not necessarily limited thereto and the number of light emitting elements OLED may vary. The first light emitting element OLED1 may emit light of a first color, the second light emitting element OLED2 may emit light of a second color, and the third light emitting element OLED3 may emit light of a third color. The first light emitting element OLED1 may overlap a first emission area PXA-R, the second light emitting element OLED2 may overlap a second emission area PXA-G, and the third light emitting element OLED3 may overlap a third emission area PXA-B. In an embodiment, the light of the first color may be red light, the light of the second color may be green light, and the light of the third color may be blue light. However, embodiments of the present inventive concept are not necessarily limited thereto and the colors emitted by each element of the light emitting element OLED may be variously arranged.

The encapsulation layer TFE may be disposed on the pixel defining layer PDL (e.g., in the third direction DR3). The encapsulation layer TFE may function to protect the light emitting elements OLED from moisture/oxygen and foreign matter. In an embodiment, the encapsulation layer TFE may include a first inorganic encapsulation layer TIL1, an organic encapsulation layer TOL, and a second inorganic encapsulation layer TIL2.

The input sensing layer ISU may be disposed on the display element layer DP-ED (e.g., disposed directly thereon in the third direction DR3). In an embodiment, the input sensing layer ISU may function to sense a user's touch and generate an electrical signal. However, embodiments of the present inventive concept are not necessarily limited thereto and the input sensing layer ISU may sense various different stimuli. In an embodiment, the input sensing layer ISU may include a sensing insulating layer ILD, a passivation layer PVX disposed on the sensing insulating layer ILD, and a sensing metal layer MTL disposed between the sensing insulating layer ILD and the passivation layer PVX.

The sensing metal layer MTL may include a first metal pattern SP1 and a second metal pattern SP2. In an embodiment, the first metal pattern SP1 and the second metal pattern SP2 may be connected to each other through a contact hole CNT extending through the sensing insulating layer ILD.

The color filter layer CFL may be disposed on the input sensing layer ISU (e.g., disposed directly thereon in the third direction DR3). The color filter layer CFL may include a plurality of color filters. In an embodiment, the color filter layer CFL may include a filter partition wall BM in which filter opening portions BM-OP are defined, and first to third color filters CF1, CF2 and CF3 respectively disposed in the filter opening portions BM-OP. However, embodiments of the present disclosure are not necessarily limited thereto and the number of the plurality of color filters included in the color filter layer CFL may vary. In an embodiment, the first color filter CF1 may transmit the red light emitted from the first light emitting element OLED1, the second color filter CF2 may transmit the green light emitted from the second light emitting element OLED2, and the third color filter CF3 may transmit the blue light emitted from the third light emitting element OLED3.

The overcoat layer OC may cover the filter partition wall BM and the first to third color filters CF1, CF2 and CF3. The overcoat layer OC may be in direct contact with the filter partition wall BM and the first to third color filters CF1, CF2 and CF3. In the present disclosure, when components are “in direct contact” with each other, it may mean that the components are in physical contact with each other with no other element disposed between the components.

In an embodiment, the overcoat layer OC may be directly disposed on the color filter layer CFL and simultaneously perform a planarization function and an impact dispersion function. In an embodiment, a Young's modulus of the overcoat layer OC may be in a range of about 3 GPa to about 10 GPa. For example, the Young's modulus of the overcoat layer OC may be in a range of about 3 GPa to about 7 GPa. For example, the Young's modulus of the overcoat layer OC may be in a range of about 4 GPa to about 6 GPa.

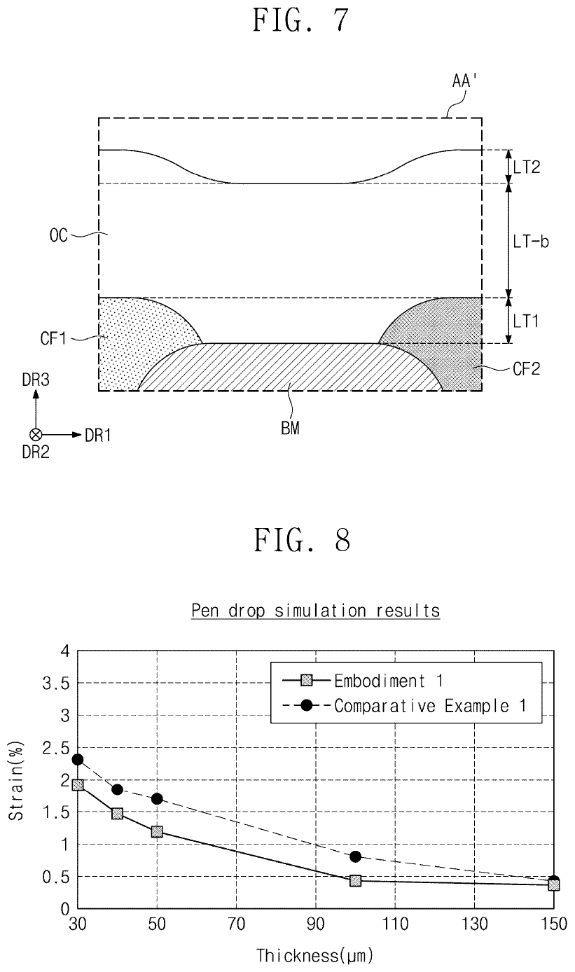

In an embodiment, a degree of planarization (DOP) of the overcoat layer OC may be greater than or equal to about 90%. This will be described in detail with reference to FIG. 7.

In an embodiment, the overcoat layer OC may have a thickness OC-TH (e.g., length in the third direction DR3) in a range of about 10 μm to about 80 μm. For example, the overcoat layer OC may have the thickness OC-TH in a range of about 10 μm to about 20 μm.

In an embodiment, the overcoat layer OC may have a single-layer structure. Accordingly, a process of manufacturing the overcoat layer OC may be simplified, and the overcoat layer OC may be provided to be relatively thin in thickness (e.g., in the third direction DR3). In an embodiment, the overcoat layer OC may include at least one material selected from polyhedral oligomeric silsesquioxane (POSS), cyclic epoxy-based resin, and acrylic resin.

In an embodiment, the overcoat layer OC may have a refractive index in a range of about 1.5 to about 1.6.

In an embodiment, the overcoat layer OC may have a visible light transmittance (e.g., light having a wavelength in a range of about 380 nm to about 780 nm) in a range greater than or equal to about 99%.

In an embodiment, the display panel DP may have a total thickness DP-TH (e.g., length in the third direction DR3) in a range of about 0.1 mm to about 0.55 mm.

The anti-reflective layer RL may be disposed on the overcoat layer OC (e.g., disposed directly thereon in the third direction DR3). The anti-reflective layer RL may be in direct contact with the overcoat layer OC.

FIG. 7 is an enlarged view of area AA′ in FIG. 6.

Hereinafter, a degree of planarization of an overcoat layer OC is described with reference to FIG. 7.

A stepped portion generated in the overcoat layer OC is illustrated in FIG. 7 and the heights of the stepped portions may be exaggerated for convenience of description.

In this embodiment, each of the first to third color filters CF1 to CF3 (see FIG. 6) may protrude further in the third direction DR3 than the filter partition wall BM does. However, embodiments of the present inventive concept are not necessarily limited thereto. For example, in some embodiments the filter partition wall BM may protrude further in the third direction DR3 than the first to third color filters CF1 to CF3.

As used herein, a first stepped portion LT1 may be defined as a largest stepped portion that the color filter layer CFL (see FIG. 6) has in the third direction DR3. A second stepped portion LT2 may be defined as a largest stepped portion that the overcoat layer OC has in the third direction DR3.

When the degree of planarization of the overcoat layer OC is X, the degree X of planarization may be defined using the following equation 1.

$$X = \{ ( first stepped portion LT 1 - second stepped portion LT 2 / first stepped portion LT 1 ) \} \times 100 ( \% ) \qquad [ Equation 1 ]$$

In this embodiment, the degree X of planarization of the overcoat layer OC may be in a range of about 90% to about 100%. For example, the overcoat layer OC may be directly disposed on the color filter layer CFL and function to reduce the stepped portion which may be generated by the color filter layer CFL. In this aspect, the overcoat layer OC may be distinguished from a general hard coating layer.

FIG. 8 is a graph illustrating experimental results for an embodiment of the present inventive concept and a comparative example. To describe the impact resistance characteristics of the display module DM (see FIG. 6), FIG. 8 shows internal stress generated in the encapsulation layer TFE (see FIG. 6) included by the display module DM according to the thickness of the overcoat layer OC (see FIG. 6).

An overcoat layer included by a display module according to Comparative Example 1 may have a Young's modulus of about 1 GPa, and the overcoat layer OC (see FIG. 6) included by the display module DM (see FIG. 6) according to Embodiment 1 of the present inventive concept may have a Young's modulus of about 5 GPa. Referring to FIG. 8, the display module DM according to Embodiment 1 may have decreased internal stress compared to the display module according to Comparative Example 1. For example, when a thickness of the overcoat layer OC is approximately 30 μm, Embodiment 1 exhibits a reduced strain percentage of approximately 1.9 whereas the Comparative Example 1 exhibits a strain percentage of approximately 2.3. When a thickness of the overcoat layer OC is approximately 100 μm, Embodiment 1 exhibits a reduced strain percentage of approximately 0.4 whereas the Comparative Example 1 exhibits a strain percentage of approximately 0.8.

Table 1 below shows results of a pen drop test carried out to investigate an influence of the thickness of the overcoat layer OC (see FIG. 6), included by the display module DM (see FIG. 6), on the impact resistance characteristics of the display module DM. In Table 1, a “pen drop height” indicates a minimum height at which a dark spot is generated on the display module DM when a pen having a standard weight and composition is dropped point-side down onto a front surface of the display module DM. When the “pen drop height” is large, it means that the display module DM (see FIG. 6) may withstand a relatively large impact. For example, the display module having a large pen drop height may have relatively excellent impact resistance characteristics.

TABLE 1

| | Comparative | Embodiment | Embodiment | Embodiment |
|---|---|---|---|---|
| | Example 2 | 2 | 3 | 4 |
| Thickness of | 0 μm | 6 μm | 15 μm | 20 μm |
| overcoat layer | | | | |
| Pen drop height | 7 cm | 15 cm | 13 cm | 11 μm |

Referring to Table 1, it may be seen that Embodiments 2 and 3 in which the display module DM (see FIG. 6) includes the overcoat layer OC (see FIG. 6) are greater in pen drop height than Comparative Example 2 in which the display module does not include the overcoat layer. However, when the experimental results according to Embodiments 2 to 4 are compared with each other, it may be seen that when the thickness of the overcoat layer OC (see FIG. 6) is about 20 μm or more, the impact resistance characteristics are rather significantly decreased. This may be because the overcoat layer is disposed on the color filter layer (e.g., disposed directly thereon in the third direction DR3). For example, during the formation of the overcoat layer OC on the color filter layer CFL (see FIG. 6), residual stress may be generated, and a residual force by this residual stress may affect an interface between components included by the display module DM. For example, when the display module DM (see FIG. 6) includes the overcoat layer having a thickness of less than about 20 μm, the impact resistance characteristics may be increased.

The experimental results according to Table 1 taken together, the thickness of the overcoat layer OC (see FIG. 6) should be within a specified range. Accordingly, the display module DM according to an embodiment of the present inventive concept may include the overcoat layer having the thickness in a range of about 5 μm to about 20 μm. For example, the display module DM according to an embodiment of the present inventive concept may include the overcoat layer having the thickness in a range of about 5 μm to about 15 μm.

The display module DM (see FIG. 6) according to an embodiment of the present inventive concept may include the overcoat layer OC (see FIG. 6) having the specific Young's modulus and thickness as previously discussed, thereby securing sufficient robustness even without including a cover glass and a polarizing layer. Accordingly, reliability of the display module DM may be increased.

According to the present inventive concept, the display module with the increased impact resistance may be provided.

In the above, description has been made with reference to non-limiting embodiments of the present inventive concept, but those skilled or of ordinary skill in the art may understand that various modifications and changes may be made to embodiments of the present inventive concept within the spirit and technical scope of the present inventive concept. Therefore, the technical scope of the present inventive concept is not to be limited to the described embodiments stated in the detailed description of the specification.

What is claimed is:

1. A display module comprising:
a base layer;
a display element layer disposed on the base layer and comprising light emitting elements;
an input sensing layer disposed on the display element layer;
a color filter layer disposed on the input sensing layer, the color filter layer comprising a filter partition wall having filter opening portions defined therein, and a plurality of color filters respectively disposed in the filter opening portions; and
an overcoat layer covering the filter partition wall and the plurality of color filters, the overcoat layer having a Young's modulus in a range of about 3 GPa to about 7 GPa and a degree of planarization in a range of about 90% to about 100%.

2. The display module of claim 1, wherein the overcoat layer has a thickness in a range of about 5 μm to about 20 μm.

3. The display module of claim 1, wherein the overcoat layer has a thickness in a range of about 5 μm to about 15 μm.

4. The display module of claim 1, wherein the overcoat layer comprises at least one material selected from polyhedral oligomeric silsesquioxane (POSS), cyclic epoxy-based resin, and acrylic resin.

5. The display module of claim 1, wherein the overcoat layer has a refractive index in a range of about 1.5 to about 1.6.

6. The display module of claim 1, wherein the overcoat layer has a visible light transmittance greater than or equal to about 99%.

7. The display module of claim 1, wherein the overcoat layer is in direct contact with the filter partition wall and the plurality of color filters.

8. The display module of claim 1, wherein the overcoat layer has a single-layer structure.

9. The display module of claim 1, further comprising an anti-reflective layer disposed on the overcoat layer.

10. The display module of claim 1, wherein the display module has a total thickness in a range of about 0.1 mm to about 0.55 mm.

11. The display module of claim 1, wherein:
the plurality of color filters comprises first to third color filters;
the first color filter transmits red light;
the second color filter transmits green light; and
the third color filter transmits blue light.

12. The display module of claim 1, wherein:
the base layer comprises glass; and
the base layer has a thickness less than or equal to about 0.2 mm.

13. The display module of claim 1, wherein the input sensing layer comprises a sensing insulating layer, a sensing metal layer disposed on the sensing insulating layer, and a passivation layer covering the sensing metal layer.

14. The display module of claim 1, wherein the display element layer comprises a first inorganic encapsulation layer covering the light emitting elements, an organic encapsulation layer disposed on the first inorganic encapsulation layer, and a second inorganic encapsulation layer disposed on the organic encapsulation layer.

15. A display module comprising:
a base layer;
a display element layer disposed on the base layer and comprising light emitting elements;
an input sensing layer disposed on the display element layer;
a color filter layer disposed on the input sensing layer, and comprising a filter partition wall having filter opening portions defined therein, and a plurality of color filters respectively disposed in the filter opening portions; and
an overcoat layer in direct contact with the filter partition wall and the plurality of color filters, the overcoat layer having a Young's modulus in a range of about 3 GPa to about 7 GPa, the overcoat layer including at least one material selected from polyhedral oligomeric silsesquioxane (POSS), cyclic epoxy-based resin, and acrylic resin.

16. The display module of claim 15, wherein the overcoat layer has a refractive index in a range of about 1.5 to about 1.6.

17. The display module of claim 15, wherein the overcoat layer has a visible light transmittance greater than or equal to about 99%.

18. The display module of claim 15, wherein the overcoat layer has a thickness in a range of about 5 μm to about 15 μm.

19. The display module of claim 15, further comprising an anti-reflective layer disposed on the overcoat layer.

20. An electronic device comprising:
a display module comprising a base layer, a display element layer disposed on the base layer and comprising light emitting elements, an input sensing layer disposed on the display element layer, a color filter layer disposed on the input sensing layer and comprising a filter partition wall having filter opening portions defined therein, and a plurality of color filters respectively disposed in the filter opening portions, and an overcoat layer covering the filter partition wall and the plurality of color filters and having a Young's modulus in a range of about 3 GPa to about 7 GPa and a degree of planarization in a range of about 90% to about 100%;
an anti-reflective layer disposed on the display module;
a window disposed on the anti-reflective layer;
a processor electrically connected to the display module; and
a housing providing a base space in which the display module is disposed.
